(19) United States
(12) Patent Application Publication
(10) Pub. No.: US 2024/0395568 A1
(43) Pub. Date: Nov. 28, 2024

(54) METHOD FOR MANUFACTURING SEMICONDUCTOR DEVICE, TEMPORARY-FIXING MATERIAL, AND APPLICATION FOR MANUFACTURING SEMICONDUCTOR DEVICE OF TEMPORARY-FIXING MATERIAL

(71) Applicant: Resonac Corporation, Minato-ku, Tokyo (JP)

(72) Inventors: Keisuke NISHIDO, Minato-ku, Tokyo (JP); Masaaki TAKEKOSHI, Minato-ku, Tokyo (JP)

(21) Appl. No.: 18/687,298

(22) PCT Filed: Sep. 2, 2022
(86) PCT No.: PCT/JP2022/033190

§ 371 Date: Feb. 28, 2024

(30) Foreign Application Priority Data
Sep. 3, 2021 (WO) PCT/JP2021/032475

(51) Int. Cl. H01L 21/56; H01L 23/00

(52) U.S. Cl. CPC H01L 21/568; H01L 21/561; H01L 24/82; H01L 24/96; H01L 2224/82; H01L 2224/96

(57) ABSTRACT

A method for manufacturing a semiconductor device, comprising: arranging a semiconductor chip on a temporary fixing material layer of a carrier substrate; forming a sealing layer sealing the semiconductor chip, thereby forming a sealing structure on the carrier substrate, the sealing structure having a connection surface in contact with the temporary fixing material layer, the semiconductor chip being exposed to the connection surface, a step formed by the semiconductor chip and the sealing layer on the connection surface being 5.0 μm or less; separating the carrier substrate from the sealing structure; and providing a redistribution layer on the connection surface.

### TECHNICAL FIELD

The present disclosure relates to a method for manufacturing a semiconductor device, a temporary fixing material, and an application of a temporary fixing material for manufacturing a semiconductor device.

### BACKGROUND ART

In order to reduce the size of an electronic device, a wafer level package in which bumps for connection to a substrate are directly provided on an electrode surface of a semiconductor chip may be employed. Further, in order to realize an increase in the number of bumps and miniaturization of wiring, there is an increasing demand for a fan-out wafer level package having wiring drawn out to an area larger than the size of a semiconductor chip.

As a method of forming a fan-out wafer level package, there is a chip first/face-down process including arranging a semiconductor chip on a temporary fixing material layer and forming a sealing layer for sealing the semiconductor chip in this state. The temporary fixing material layer is peeled off from the sealing layer and the semiconductor chip after the sealing layer is formed (for example, Patent Documents 1 and 2).

### CITATION LIST

### Patent Literature

Patent Document 1: Japanese Patent No. 3594853
Patent Document 2: Japanese Unexamined Patent Publication No. 2013-098393

### SUMMARY OF INVENTION

### Technical Problem

In the case of forming a sealing layer for sealing a semiconductor chip arranged on a temporary fixing material layer, when the temporary fixing material layer is peeled off from the sealing layer and the semiconductor chip, a surface on which the sealing layer and the semiconductor chip are exposed is formed. At this time, since the semiconductor chip protrudes higher than the surface of the sealing layer, a minute step may be formed between the semiconductor chip and the sealing layer. In this step, when a redistribution layer connected to the semiconductor chip is formed, there is a possibility that a stress singular point caused by a difference in thermal expansion coefficient between the semiconductor chip and the sealing material is generated in the vicinity of the step. In particular, when the redistribution layer includes fine wiring and a thin insulating layer, there is a concern that the stress singularity may cause cracks or peeling in the redistribution layer.

### Solution to Problem

The present disclosure includes the followings

[1] A method of manufacturing a semiconductor device, comprising:
preparing a carrier substrate comprising a support and a temporary fixing material layer provided on the support;
arranging a semiconductor chip comprising a chip main body portion and an electrode pad provided on an outer surface of the chip main body portion on the temporary fixing material layer;
forming a sealing layer sealing the semiconductor chip, thereby forming a sealing structure comprising the semiconductor chip and the sealing layer on the carrier substrate, the sealing structure comprising a connection surface in contact with the temporary fixing material layer, the semiconductor chip being exposed to the connection surface, and a step formed by the semiconductor chip and the sealing layer on the connection surface being 5.0 μm or less; and Separating the carrier substrate from the sealing structure;
providing a redistribution layer comprising multilayer wirings connected to the electrode pad and an insulating layer filling a space between the wirings on the connection surface of the sealing structure, in this order.

[2] The method according to [1], wherein a thickness of the temporary fixing material is 50 μm or less.

[3] The method according to [1], wherein a thickness of the temporary fixing material layer is more than 10 μm and 50 μm or less.

[4] The method according to any one of [1] to [3], wherein a tensile elastic modulus of the support at 23° C. is 100 GPa or more.

[5] The method according to any one of [1] to [4], wherein the support is a glass plate, a metal plate, a silicon wafer, or a ceramic plate.

[6] The method according to [1], wherein a thickness of the temporary fixing material layer and a tensile elastic modulus of the support at 23° C. are selected in a range such that the step is 5.0 μm or less.

[7] The method according to [6], wherein a thickness of the temporary fixing material layer is selected in a range of 50 μm or less.

[8] The method according to [6], wherein a thickness of the temporary fixing material layer is selected in a range of more than 10 μm and 50 μm or less.

[9] The method according to any one of [6] to [8], a tensile elastic modulus of the support at 23° C. is selected in the range of 100 GPa or more.

[10] The method according to any one of [6] to [9], wherein the support is selected from a glass plate, a metal plate, a silicon wafer, and a ceramic plate.

[11] The method according to any one of [1] to [10], wherein the insulating layer comprises an intermediate layer interposed between the wirings and the sealing structure, and a maximum value of a thickness of the intermediate layer is 15 μm or less.

[12 ] The method according to any one of [1] to [11], wherein the sealing layer is formed by compression molding comprising heating and pressurizing a granular sealing material comprising a curable resin and an inorganic filler in a mold.

[13] The method according to any one of [1] to [11], wherein the sealing layer is formed by a method comprising laminating a film-shaped sealing material comprising a curable resin and an inorganic filler on the carrier substrate.

[14] A film-shaped temporary fixing material for manufacturing a semiconductor device having a thickness of 50 μm or less and used as a temporary fixing material layer in the method according to any one of [1] to [13].

[15] A film-shaped temporary fixing material for manufacturing a semiconductor device having a thickness of more than 10 μm and 50 μm or less and used as a temporary fixing material layer in the method according to any one of [1] to [13].

[16] An application of a film-shaped temporary fixing material having a thickness of 50 μm or less, for manufacturing a semiconductor device according to the method according to any one of [1] to [13].

[17] An application of a film-shaped temporary fixing material having a thickness of more than 10 μm and 50 μm or less, for manufacturing a semiconductor device according to the method according any one of [1] to [13].

### Advantageous Effects of Invention

According to an aspect of the present disclosure, it is possible to efficiently manufacture a semiconductor device while reducing the possibility of occurrence of stress singularities in a redistribution layer.

### BRIEF DESCRIPTION OF DRAWINGS

FIG. 1 is a step diagram showing an example of a method for manufacturing a semiconductor device.

FIG. 2 is a step diagram showing an example of a method for manufacturing a semiconductor device.

FIG. 3 is a schematic view showing an example of a step formed by a semiconductor chip and a sealing layer.

### DESCRIPTION OF EMBODIMENTS

The present invention is not limited to the following examples. The dimensional ratios in the drawings are not limited to the illustrated ratios. In the present specification, a numerical value range indicated using “to” includes numerical values described before and after “to” as a minimum value and a maximum value, respectively.

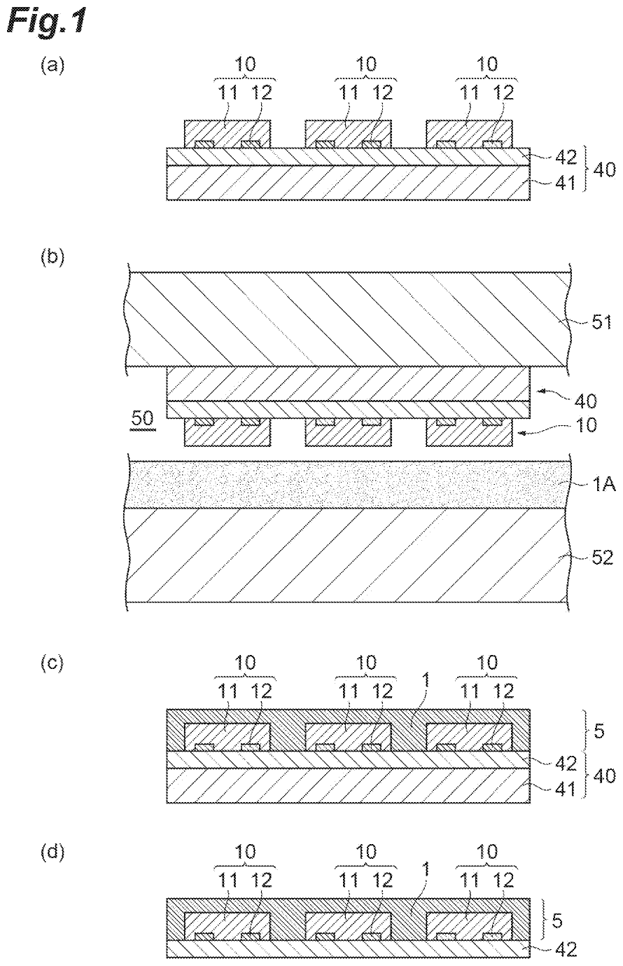

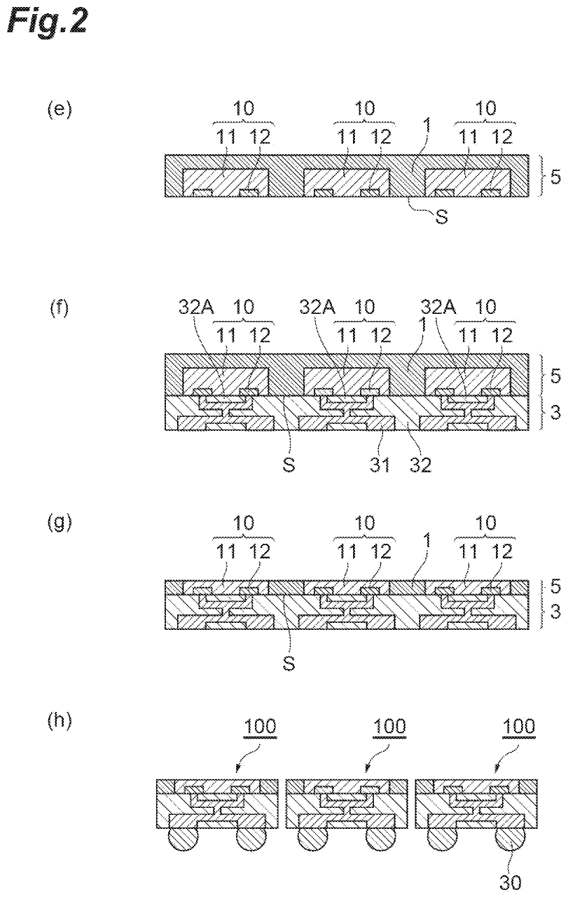

FIGS. 1 and 2 are step diagrams showing an example of a method for manufacturing a semiconductor device. The method shown in FIGS. 1 and 2 is an example of an assembly process for manufacturing a chip-first/face-down fan-out wafer level package. The method is mainly comprised of preparing a carrier substrate 40 comprising a support 41 and a temporary fixing material layer 42 on the support 41, arranging a plurality of semiconductor chips 10 having a chip main body portion 11 and an electrode pad 12 on an outer surface of the chip main body portion 11 on one the temporary fixing material layer 42 in a direction in which the electrode pad 12 contacts the temporary fixing material layer 42, and forming a sealing layer 1 sealing the semiconductor chip 10, thereby forming a sealing structure 5 comprising the semiconductor chip 10 and the sealing layer 1 on the carrier substrate 40, the sealing structure 5 having a connection surface in contact with the temporary fixing material layer 42, the semiconductor chip 10 being exposed to the connection surface (FIGS. 1(b), (c)), separating the carrier substrate 40 from the sealing structure 5 (FIG. 1(d)), providing a redistribution layer 3 including multilayer wirings 31 connected to the electrode pad 12 and an insulating layer 32 filing a space between the wirings on the connection surface S of the sealing structure 5 (FIG. 2(f)), grinding the sealing structure 5 from the surface opposite to the connection surface S(FIG. 1(g)), providing a solder ball 30 connected to the wirings 31 on the surface of the redistribution layer opposite to the sealing structure 5 (FIG. 2(h)), and dividing the sealing structure 5 together with the redistribution layer 3 to obtain individualized semiconductor devices 100 (FIG. 2(h)).

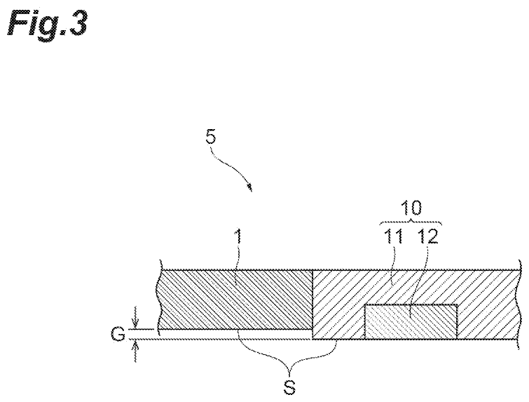

FIG. 3 is a pattern diagram showing an example of steps formed by the semiconductor chip 10 and the sealing layer 1 in the connection surface S when the sealing structure 5 is formed. As shown in FIG. 3, a slight protrusion of the semiconductor chip 10 in the connection surface S creates a step G between the semiconductor chip 10 and the sealing layer 1. In the method according to the present disclosure, the sealing structure 5 having the step G of 5.0 μm or less is formed. A small the step G can reduce the likelihood of stress-singularities due to the step G when the redistribution layer 3 is formed. From this point of view, the step G may be 4.9 μm or less, 4.8 μm or less, 4.7 μm or less, 4.6 μm or less, 4.5 μm or less, 4.4 μm or less, 4.3 μm or less, 4.2 μm or less, 4.1 μm or less, 4.0 μm or less, 3.9 μm or less, 3.8 μm or less, 3.7 μm or less, 3.6 μm or less, 3.5 μm or less, 3.4 μm or less, or 3.3 μm or less. The step G may be 0 μm or more, 0.1 μm or more, 0.2 μm or more, 0.3 μm or more, 0.4 μm or more, 0.5 μm or more, 0.6 μm or more, 0.7 μm or more, 0.8 μm or more, 0.9 μm or more, or 1.0 μm or more. The step G can be measured after the carrier substrate 40 has been removed by analyzing the exposed surfaces of the connection surface S using, for example, a contact profilometer.

For example, the thickness of the temporary fixing material layer 42 and the tensile elastic modulus of the support 41 can be selected so that the step G is 5.0 μm or less.

When the thickness of the temporary fixing material layer 42 is small, the step G tends to be small. The thickness of the temporary fixing material layer 42 may be selected within a range of, for example, 50 μm or less, 45 μm or less, 40 μm or less, or 35 μm or less. The lower limit of the thickness of the temporary fixing material layer 42 is usually about 1 μm. The thickness of the temporary fixing material layer 42 may be greater than 10 μm.

When the tensile elastic modulus (Young modulus) of the support 41 is large, the step G tends to be small. The tensile elastic modulus of the support 41 may be selected, for example, in the range of 100 GPa or more, or 110 GPa or more. The upper limit of the tensile elastic modulus of the support 41 is usually about 300 GPa. The conditions of the tensile test for measuring the tensile elastic modulus can be selected according to a measurement method corresponding to the material of the support. Examples of the adopted measurement method are JIS-K7161-1 when the material of the support is an organic material (for example, resins), JIS-R1602 when the material of the support is ceramics or glass, and JIS-7.2280 when the material of the support is metals. The Young's modulus is sometimes referred to as a longitudinal elastic modulus. Since the tensile elastic modulus generally has temperature dependence, the value of the tensile elastic modulus at 23° C. is referred to for selection of the support.

The temporary fixing material layer 42 thickness, the support 41 tensile elastic modulus, and the support 41 thickness may be selected such that the step G is 5.0 μm or less. In this case, the thickness of the temporary fixing material layer 42 and the tensile elastic modulus of the support 41 may be selected from the above-described ranges. When the thickness of the support 41 is large, the step G tends to be small. The thickness of the support 41 may be selected in a range of 0.5 mm or more, 0.6 mm or more, 0.7 mm or more, 0.8 mm or more, 0.9 mm or more, 1.0 mm or more, or greater than 1.0 mm. The upper limit of the thickness of the support 41 is usually about 4.0) mm.

The support 41 may be, for example, a glass plate, a metal plate (e.g., copper plate, stainless steel plate), a silicon wafer, a ceramic plate, or an organic substrate. The support 41 may be glass plate, metal plate, silicon wafer, or ceramic plate, and may be glass plate, metal plate, or silicon wafer. They usually have a 100 GPa or more tensile elastic modulus at 23° C.′. When the temporary fixing material layer 42 is peeled by UV or laser radiation, most typically the support 41 is a glass plate. The metal plate is advantageous in terms of flat surfaces and durability in the sealing layer formation step. The support 41 may be disk-shaped, and may have a size similar to that of the silicon wafer (for example, about 12 inches). The support 41 may be a plate-shaped body having a rectangular main surface, and in this case, one side of the main surface may be about a 600 mm.

The support 41 may be substantially free of expandable particles. In particular, the support 41 may be an organic substrate substantially free of expandable particles. Here, the expandable particles mean particles capable of forming irregularities on the support 41 by expanding themselves by external portion stimulation and reducing the adhesive force with an adherend. Examples of the expandable particle include a thermally expandable particle (for example, a microcapsule or a foaming agent) which expands by heating and an energy linear expansion particle which expands by irradiation with an energy ray. “Substantially free of expandable particles” means that the content of expandable particles is less than 1% by weight relative to the weight of the support 41.

Alignment marks for positioning the semiconductor chip 10 may be provided on the temporary fixing material layer 42 side surface of the support 41. The alignment mark can be formed using an arbitrary material such as metal or resin. Alignment marks may be inscribed on the support 41 itself. When an alignment mark is provided, the temporary fixing material layer 42 may be transparent enough to allow the alignment mark to be visually recognized.

The material forming the temporary fixing material layer 42 can be selected based on thickness or the like from materials used for the purpose of temporary fixing or temporary bonding in the manufacture of the semiconductor device. A commercially available protective tape for semiconductor manufacture may be used as the temporary fixing material layer. The temporary fixing material layer 42 may be a single layer of film or a laminate comprising two layers above.

The semiconductor chip 10 is a face-down type chip having a plate-shaped chip main body portion 11 having two main surfaces and a plurality of the electrode pad 12 formed on one main surface of the chip main body portion 11. The chip main body portion 11 may be a bare chip. The maximum widths of the semiconductor chips may be, for example, 100 μm or more 50000 μm or less. The semiconductor chip is not limited thereto, and an arbitrary semiconductor chip having a different size, material, attached matter, function, or the like can be selected as necessary.

The method of arranging the semiconductor chip 10 on the temporary fixing material layer 42 is not particularly limited. Any device and method such as a die bonder normally used in the manufacture step of a semiconductor device can be applied. Conditions including temperature, pressure, application time and the like can also be arbitrarily set. The semiconductor chip 10 may be arranged on the temporary fixing material layer 42 under the condition that the temperature of the temporary fixing material layer 42 is 20 to 230° C. The number of semiconductor chips arranged on one the temporary fixing material layer 42 may be 1 or 2 or more, and may be 30000 or less.

FIG. 1b illustrates an example of a step of forming a sealing layer by compression molding. Here, in a cavity 50 between a pair of a mold 51, 52 arranged facing each other, a structure composed of the carrier substrate 40 and the semiconductor chip 10 temporarily fixed thereto and a sealing material 1A are arranged at positions facing each other in a direction in which the semiconductor chip 10 is inside. The carrier substrate 40, the semiconductor chip 10, and the sealing material 1A are then heated and pressurized in the cavity 50. This creates the sealing structure 5 on the temporary fixing material layer 42 with the sealing layer 1 that seals the semiconductor chip 10.

The sealing material 1A may be solid granular at room temperature (25° C.). The granular the sealing material 1A may have an average particle size of 1.0 to 7.0 mm or 2.0 to 3.5 mm. The particle size here means the maximum width of the individual particles. The individual particles of the granular the sealing material 1A may be agglomerates formed from a powder of the sealing material.

The heating temperature in compression molding (hereinafter sometimes referred to as “sealing temperature”) may be 100° C. or more and 150° C.′ or less. The sealing temperature is typically the temperature of the mold 51, 52 used for compression molding. The sealing temperature is set in the range of the temperature at which the sealing material 1A is cured. When the sealing temperature is 150° C. or less, thermal shrinkage when the formed the sealing layer 1 is cooled to room temperature is suppressed to be particularly low, which may contribute to further reduction of a minute step formed by the semiconductor chip and the sealing layer. From the same viewpoint, the sealing temperature may be 130° C. or lower. When the sealing temperature is 100° C. or more, it is easy to sufficiently cure the sealing layer 1 in a moderately short time. If necessary, the sealing structure 5 removed from the mold 51, 52 may be further heated.

The sealing material 1A may have a mold shrinkage of 0.5% or less, 0.4% or less, or 0.3% or less. The molding shrinkage is a value Sm calculated by the formula: Sm={(Lb−La)/Lb}×100, where La is the volume of the sealing layer 1 at 25° C. and Lb is the volume of the sealing layer 1 at the sealing temperature. The of a portion of the cavity 50 formed by the mold 51, 52 occupied by the sealing layer 1 at the sealing temperature may be used as Lb. The small molding shrinkage rate can contribute to further reduction of the step G formed by the semiconductor chip and the sealing layer.

The thickness of the semiconductor chip 10 may be ⅓ or less, or ¼ or less of the thickness of the sealing layer 1. The sealing layer 1 thickness here means the maximum value of the sealing layer 1 thickness in a direction perpendicular to the connection surface S of the sealing structure 5, which usually corresponds to the thickness of the sealing structure 5 with the semiconductor chip 10. When the ratio of the thickness of the semiconductor chip 10 to the thickness of the sealing layer 1 is small, the influence of the semiconductor chip 10 having a relatively small shrinkage ratio becomes small, and as a result, the minute step formed by the semiconductor chip and the sealing layer tends to be more significantly reduced. From the same viewpoint, the thickness of the semiconductor chip 10 may be ¼ or less of the thickness of the scaling layer 1.

The granular the sealing material 1A may contain a curable resin and an inorganic filler. The sealing material containing a somewhat large amount of inorganic filler is solid at room temperature (25° C.) and easily maintains a granular form. From the viewpoint of maintaining the granular form and reducing the thermal shrinkage ratio, the content of the inorganic filler may be 55 vol % to 90 vol %, 60 vol % to 90 vol %, or 70 vol % to 85 vol % based on the sealing material 1A. When the content of the inorganic filler is large, the reflow resistance tends to be improved. When the content of the inorganic filler is small, the filling property tends to be improved.

The inorganic filler may be, for example, particles containing one or more inorganic material selected from fused silica, crystalline silica, alumina, zircon, calcium silicate, calcium carbonate, potassium titanate, silicon carbide, silicon nitride, aluminum nitride, boron nitride, beryllia, zirconia, zircon, forsterite, steatite, spinel, mullite, and titania. The inorganic filler may be glass fiber. The inorganic filler containing an inorganic material selected from aluminum hydroxide, magnesium hydroxide, zinc borate, and zinc molybdate is also useful from the viewpoint of improving flame retardancy. The inorganic filler may contain fused silica from the in linear expansion coefficient, the inorganic filler may contain fused silica. From the viewpoint of high thermal conductivity, the inorganic filler may contain alumina. The shape of the inorganic filler is not particularly limited, but may be, for example, a spherical shape in terms of filling properties and mold abrasion properties. These inorganic fillers are incorporated into the sealing material either alone or in combination of the two above.

The curable resins constituting the sealing material 1A may be, for example, epoxy resins, in which case the sealing material 1A may further contain a curing agent for epoxy resins.

The epoxy resin is not particularly limited as long as it is generally used in a sealing material. Specific examples of the epoxy resins include novolak epoxy resins such as phenol novolak epoxy resins, orthocresol novolak epoxy resins, and epoxy resins having a triphenylmethane skeleton; bisphenol epoxy resins such as a bisphenol A, a bisphenol F, a bisphenol S, and diglycidyl ethers of alkyl-substituted or unsubstituted biphenols; stilbene epoxy resins; hydroquinone epoxy resins; glycidyl ester epoxy resins; glycidylamine epoxy resins; epoxidized products of cocondensation resins of dicyclopentadiene and phenols; naphthalene ring-containing epoxy resins; epoxidized products of aralkyl phenol resins such as phenol-aralkyl resins and naphthol-aralkyl resins; trimethylolpropane epoxy resins; terpene-modified epoxy resins; linear aliphatic epoxy resins obtained by oxidizing an olefin bond with a peracid such as peracetic acid; alicyclic epoxy resins; and sulfur atom containing epoxy resins. An epoxy resin that is solid or has a high viscosity at room temperature (25° C.) tends to form a cured product that exhibits relatively small curing shrinkage and heat shrinkage compared to a liquid epoxy resin.

The curing agent is not particularly limited as long as it is generally used as a curing agent for epoxy resins. Specific examples of the curing agent include a novolac type phenol resin, a phenol-aralkyl resin, an aralkyl type phenol resin, a dicyclopentadiene type phenol novolac resin, and a terpene modified phenol resin.

The sealing material 1A may further contain a curing accelerator, and examples thereof include addition products of a phosphine compound and a quinone compound. The content of the curing accelerator (or the addition product of the phosphine compound and the quinone compound) in the sealing material 1A may be 0.3 to 0.05% by weight or 0.2 to 0.1% by weight based on the weight of the sealing material 1A from the viewpoint of curing time. The content of the addition reaction product of the phosphine compound and the quinone compound may be 0.5 to 5% by mass or 1 to 3% by mass relative to the amount of the epoxy resin from the viewpoint of the curing time.

The sealing material 1A may further comprise coupling agents. The coupling agent can increase adhesion between the inorganic filler and other resin components. From the viewpoint of filling properties, the sealing material 1A may contain a silane-coupling agent having an epoxy group.

When the sealing material 1A contains the coupling agents, the content thereof may be 0.037% by weight to 4.75% by weight based on the weight of the sealing material 1A. When the content of the coupling agents is 0.037% by weight or more, the adhesion to the sealing layer 1 tends to be improved. When the content of the coupling agents is 4.75% by weight or less, the formability of the sealing material 1A tends to be improved. From the same viewpoint, the content of the coupling agent may be 0.05% by mass to 3% by mass or 0.1% by mass to 2.5% by mass.

The coupling agent is not particularly limited, and may be, for example, various silane-based compounds (silane coupling agents) such as silane compounds having at least one amino group selected from primary amino groups, secondary amino groups, and tertiary amino groups, epoxysilanes, mercaptosilanes, alkylsilanes, ureidosilanes, and vinylsilanes, titanium-based compounds (titanate-based coupling agents), aluminum chelates, and aluminum/zirconium-based compounds.

Specific examples of the coupling agent include silane coupling agents having an unsaturated bond such as vinyltrichlorosilane, vinyltriethoxysilane, vinyltris(β-methoxyethoxy) silane, γ-methacryloxypropyltrimethoxysilane, and vinyltriacetoxysilane; silane coupling agents having an epoxy group such as β-(3,4-epoxycyclohexyl)ethyltrimethoxysilane, γ-glycidoxypropyltrimethoxysilane, and γ-glycidoxypropylmethyldimethoxysilane; silane-based coupling agents such as γ-mercaptopropyltrimethoxysilane, γ-aminopropyltrimethoxysilane, γ-aminopropylmethyldimethoxysilane, γ-aminopropyltriethoxysilane, γ-aminopropylmethyldiethoxysilane, γ-anilinopropyltrimethoxysilane, γ-anilinopropyltriethoxysilane, γ-(N,N-dimethyl)aminopropyltrimethoxysilane, γ-(N,N-diethyl)aminopropyltrimethoxysilane, γ-(N,N-dibutyl)aminopropyltrimethoxysilane, γ-(N-methyl) anilinopropyltrimethoxysilane, γ-(N-ethyl) anilinopropyltrimethoxysilane, γ-(N,N-dimethyl)aminopropyltriethoxysilane, γ-(N,N-diethyl)aminopropyltriethoxysilane, γ-(N,N-dibutyl)aminopropyltriethoxysilane, γ-(N-methyl) anilinopropyltriethoxysilane, γ-(N-ethyl) anilinopropyltriethoxysilane, γ-(N,N-dimethyl)aminopropylmethyldimethoxysilane, γ-(N,N-diethyl)aminopropylmethyldimethoxysilane, γ-(N,N-dibutyl)aminopropyltrimethoxysilane, γ-(N,N-methyl) anilinopropyltrimethoxysilane, γ-(N,N-diethyl)aminopropyltriethoxysilane, γ-(N,N-dibutyl)aminopropylmethyldimethoxysilane, γ-(N-methyl) anilinopropylmethyldimethoxysilane, N-(trimethoxysilylpropyl)ethylenediamine, N-(dimethoxymethylsilylisopropyl)ethylenediamine, methyltrimethoxysilane, dimethyldimethoxysilane, methyltriethoxysilane, γ-chloropropyltrimethoxysilane, hexamethyldisilane, vinyltrimethoxysilane, and γ-mercaptopropylmethyldimethoxysilane; and titanate-based coupling agents such as isopropyl triisostearoyl titanate, isopropyl tris(dioctylpyrophosphate) titanate, isopropyl tri(N-aminoethyl-aminoethyl) titanate, tetraoctyl bis(ditridecylphosphite) titanate, tetra(2,2-diaryloxymethyl-1-butyl)bis(ditridecyl)phosphite titanate, bis(dioctylpyrophosphate) oxyacetate titanate, bis(dioctylpyrophosphate) ethylene titanate, isopropyl trioctanoyl titanate, isopropyl dimethacryl isostearyl titanate, isopropyl tridodecylbenzenesulfonyl titanate, isopropyl isostearyl diacryl titanate, isopropyl tri (dioctyl phosphate) titanate, isopropyl tricumylphenyl titanate, and tetraisopropyl bis(dioctyl phosphate) titanate.

The sealing layer 1 may be formed by a method comprising laminating a film-shaped sealing material onto the carrier substrate 40.

The film-shaped sealing material may include a curable resin composition containing a curable resin and an inorganic filler, and may be B-staged.

The heat-curable resin composition constituting the film-shaped sealing material may contain an epoxy resin or a melamine resin as the curable resin, or may contain an epoxy resin and a curing agent thereof.

The heat-curable resin composition constituting the film-shaped sealing material may contain an epoxy resin that is liquid at 25° C. “Epoxy resins which are liquid at 25° C.” means epoxy resins having a viscosity of not more than 400 Pa's at 25° C. Here, the viscosity is a value measured using an E-type viscometer or a B-type viscometer. Examples of epoxy resins that are liquid at 25° C. include the bisphenol A epoxy resins and the bisphenol F epoxy resins. The content of the epoxy resin that is liquid at 25° C. may be 30 mass % or more, 35 mass % or more, 37 mass % or more, or 40 mass % or more, and may be 70 mass % or less, or 65 mass % or less, based on the total amount of the epoxy resin and the curing agent. The content of the epoxy resin that is liquid at 25° C. may be 60 mass % or more, 65 mass % or more, or 70 mass % or more, and may be 100 mass % or less, 95 mass % or less, or 90 mass % or less, based on the total amount of the epoxy resin.

The heat-curable resin composition constituting the film-shaped sealing material may further contain an epoxy resin other than the epoxy resin that is liquid at 25° C., and examples thereof include naphthalene type epoxy resins (tetrafunctional naphthalene type epoxy resins, trifunctional naphthalene type epoxy resins, etc.), anthracene type epoxy resins, trisphenylmethane type epoxy resins, dicyclopentadiene type epoxy resins, biphenylaralkyl type epoxy resins, phenol novolac type epoxy resins, cresol novolac type epoxy resins (o-cresol novolac type epoxy resins, etc.), dihydroxybenzene novolac type epoxy resins, glycidyl ester type epoxy resins, glycidylamine type epoxy resins, hydantoin type epoxy resins, and isocyanurate type epoxy resins. One type may be selected from these.

Examples of the curing agent include phenol resins, acid anhydrides, imidazole compounds, aliphatic amines, and alicyclic amines. One of these above may be selected.

Examples of the phenol resin as a curing agent include novolak type phenol resins (resins obtained by condensation or co-condensation of phenols and aldehydes in the presence of an acidic catalyst); trisphenylmethane type phenol resins; polyparavinylphenol resins; phenol-aralkyl resins (phenol-aralkyl resins having a xylylene group synthesized from phenols and dimethoxyparaxylene); and phenol resins having a biphenyl skeleton (biphenylaralkyl type phenol resins). One of these may be selected above. Examples of phenolics from which the phenolic resins are derived include phenol, cresols, xylenols, resorcins, catechols, the bisphenol A, and the bisphenol F. Examples of aldehydes from which phenolic resins are derived include formaldehyde, acetaldehyde, propionaldehyde, benzaldehyde, and salicylaldehyde. The curing agent may include a biphenyl aralkyl type phenol resin, a novolac type phenol resin, or a combination thereof.

The ratio of the glycidyl group equivalent (epoxy equivalent) of the epoxy resin to the equivalent of the functional group (for example, a phenolic hydroxyl group) in the curing agent that reacts with the glycidyl group (for example, hydroxyl group equivalent) (the glycidyl group equivalent of (A) epoxy resin/the equivalent of the functional group in the curing agent that reacts with the glycidyl group) may be 0.7 or more, 0.8 or more, or 0.9 or more, and may be 2.0 or less, 1.8 or less, or 1.7 or less.

Examples of the inorganic filler contained in the heat-curable resin composition constituting the film-shaped sealing material include barium sulfate; barium titanate; silicas such as amorphous silica, crystalline silica, fused silica, and spherical silica; talc; clay; magnesium carbonate; calcium carbonate; aluminum oxide; aluminum hydroxide; silicon nitride; and aluminum nitride. One type or more may be selected from these. The inorganic filler may be silicas or the like.

The content of the inorganic filler in the film-shaped sealing material may be 50 mass % or more, 60 mass % or more, or 70 mass % or more, and may be 95 mass % or less, or 90 mass % or less based on the total amount of the sealing material (excluding the solvent such as an organic solvent).

The inorganic filler contained in the film-shaped sealing material may be surface-modified. The inorganic filler may be surface-modified with a silane coupling agent. Examples of the silane coupling agent include alkylsilane, alkoxysilane, vinylsilane, epoxysilane, aminosilane, acrylsilane, methacrylsilane, mercaptosilane, sulfidosilane, isocyanatosilane, isocyaninaurate silane, ureidosilane, sulfursilane, styrylsilane, alkylchlorosilane, and silane having an acid anhydride group. The silane coupling agent may be at least one selected from the group consisting of phenylaminosilane and silane having an acid anhydride group.

The average grain size of the inorganic filler included in the film-shaped sealing material may be 0.01 μm or more, 0.1 μm or more, 0.3 μm or more, 5.0 μm or more, 5.2 μm or more, or 5.5 μm or more, and may be 50 μm or less, 25 μm or less, or 10 μm or less. The average particle diameter of the inorganic filler contained in the granular sealing material may also be in the same range as above.

The film-shaped sealing material may further contain (D) a curing accelerator. The curing accelerator may be, for example, at least one selected from the group consisting of an amine-based curing accelerator, an imidazole-based curing accelerator, a urea-based curing accelerator, and a phosphorus-based curing accelerator. Examples of the amine-based curing accelerator include 1,8-diazabicyclo[5.4.0]7-undecene, 1,5-diazabicyclo[4.3.0]-5-nonene may be mentioned. Examples of the imidazole-based curing accelerator include 2-phenyl-4-methylimidazole, 2-ethyl-4-methylimidazole, and 1-cyanoethyl-2-ethyl-4-methylimidazole. An example of the urea-based curing accelerator is 3-phenyl-1,1-dimethylurea. Examples of the phosphorus-based curing accelerator include triphenylphosphine and an addition reaction product thereof, (4-hydroxyphenyl)diphenylphosphine, bis(4-hydroxyphenyl)phenylphosphine, and tris(4-hydroxyphenyl)phosphine. The curing accelerator may be an imidazole-based curing accelerator.

The content of the curing accelerator in the film-shaped sealing material may be 0.01 mass % or more, 0.1 mass % or more, or 0.3 mass % or more, and may be 5 mass % or less, 3 mass % or less, or 1.5 mass % or less based on the total amount of the epoxy resin and the curing agent.

The film or granular sealing material may further contain other additives. Examples of other additives include pigments, dyes, mold release agents, antioxidants, stress modifiers, coupling agents, surface tension modifiers, ion exchangers, colorants, and flame retardants.

A metal layer (metal foil or the like) may be laminated on the surface of the film-shaped sealing material. A concavo-convex pattern may be formed on the surface of the metal layer. A metal foil or a polymer film may be provided on the surface of the sealing material opposite the metal layer. Examples of the polymer film include polyolefin films such as a polyethylene film and a polypropylene film; polyester films such as a polyethylene terephthalate film; polyvinyl chloride films; polycarbonate films; acetylcellulose films; and tetrafluoroethylene films. The thickness of the polymer film may be 12 to 100 μm.

After the sealing layer 1 is formed, the carrier substrate 40 is separated from the sealing structure 5 by a method that includes separating the support 41 from the temporary fixing material layer 42 and peeling the temporary fixing material layer 42 from the sealing structure 5, as shown in FIGS. 1d and 2e. The method for separating the support 41 and the temporary fixing material layer 42 is not particularly limited, and for example, a method selected from heating, UV irradiation, laser irradiation, and mechanical division may be used. The method of peeling the temporary fixing material layer 42 from the sealing structure 5 is not particularly limited, and for example, a method selected from mechanical peeling and solvent washing can be used. When the temporary fixing material layer 42 is formed of a thermal foam or a thermo-plastic, for example, the temporary fixing material layer 42 can be peeled off while the sealing structure 5 is heated on a hotplate.

After the carrier substrate 40 is removed, the redistribution layer 3 is formed on the connection surface S as shown in FIG. 2f. The redistribution layer 3 has multilayer wirings 31 connected to an electrode pad 12 and an insulating layer 32 that fills the space between the wirings 31. In other words, the wirings 31 are provided in the insulating layer 32.

The wiring 31 includes a portion of the plurality of layers extending in a direction parallel to the connection surface S and a portion extending in a direction perpendicular to the connection surface S. The wiring 31 widths in a direction parallel to the connection surface S may be, for example, 10 μm or less, 9 μm or less, 8 μm or less, 7 μm or less, or 6 μm or less, and may be 1 μm or more. The breadth of the wiring 31 here means the minimum breadth of the wiring 31 in a direction parallel to the connection surface S. When the step formed by the semiconductor chip 10 and the sealing layer 1 is sufficiently small, a redistribution layer including a minute the wiring 31 having a minute width can be easily formed with high accuracy. The minimum widths of the insulating layer 32 filling between the adjacent the wiring 31 may be in the same range as described above.

The insulating layer 32 typically has an intermediate layer 32A intervening between the wiring 31 and the sealing structure 5. The maximum value of the thickness of the intermediate layer 32A may be 15 μm or less, 14 μm or less, 13 μm or less, 12 μm or less, 11 μm or less, 10 μm or less, 9 μm or less, 8 μm or less, 7 μm or less, or 6 μm or less, and may be a 1 μm or more. It is considered that even if the intermediate layer 32A is thin, if the step G is sufficiently small, the influence of the stress-specific point is hardly exerted.

The method of forming the redistribution layer 3 is not particularly limited, and for example, a semi-additive method or a method similar thereto can be adopted. The wiring 31 may be, for example, a metallic wiring formed of a metallic material such as cupper or titanium. The insulating layer 32 can be formed of, for example, photosensitive resins. For example, the insulating layer 32 is formed using photosensitive resins, and a copper-wiring the wiring 31 is formed by a semi-additive method or the like, so that the redistribution layer 3 including a fine the wiring 31 can be easily formed.

The photosensitive polymer for forming the insulating layer 32 is not particularly limited, and may be, for example, a photosensitive polymer composition containing (A) an alkali-soluble polymer, (B) a compound that generates an acid by light, (C) a thermal crosslinking agent, and (D) an acrylic resin.

The alkali-soluble resin (A) may be, for example, a polymer containing a structural unit represented by the following formula (1).

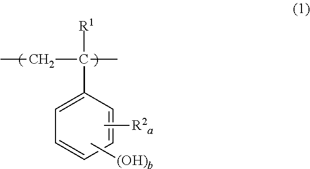

In the formula (1), R¹ represents hydrogen atom atom or methyl; R² represents alkyl groups of a carbon number 1˜10, aryl groups of a carbon number 6˜10, or alkoxy groups of the carbon number 1˜10; a represents an integer of 0 to 3; and b represents an integer of 1 to 3. The alkali-soluble resin is obtained by polymerizing a monomer giving a structural unit represented by the formula (1).

Examples of the alkyl groups of the carbon number 1˜10 represented by R² in (1) include methyl, ethyl, propyl, butyl, pentyl, hexyl, heptyl, octyl, nonyl, and decyl groups. These groups may be straight-chain or branched-chain. The carbon number 6˜10 aryl groups include, for example, phenyl and naphthyl groups. Examples of the alkoxy group in the carbon number 1˜10 include methoxy, ethoxy, propoxy, butoxy, pentoxy, hexoxy, heptoxy, octoxy, nonoxy, and decoxy groups. These groups may be straight-chain or branched-chain.

Examples of the monomer giving the structural unit represented by the formula (1) include p-hydroxystyrene, m-hydroxystyrene, o-hydroxystyrene, p-isopropenylphenol, m-isopropenylphenol, and o-isopropenylphenol. These monomers may be used alone or in combination of two kinds thereof.

Examples of the compound (B) capable of generating an acid by light include o-quinonediazide compounds, aryldiazonium salts, diaryliodonium salts, and triarylsulfonium salts. (B) The compound that generates an acid by light may be one of these compounds or a combination of two or more. An o-quinonediazide compound may be used because of its high sensitivity.

Examples of the thermal crosslinking agent (C) include compounds having a phenolic hydroxyl group, compounds having a hydroxymethylamino group, and compounds having an epoxy group. The term “compound having a phenolic hydroxyl group” used herein does not include the alkali-soluble resin (A). The compound having a phenolic hydroxyl group as a thermal crosslinking agent can not only serve as a thermal crosslinking agent but also increase the dissolution rate of an exposed portion during development with an alkali aqueous solution and improve sensitivity. The weight average molecular weight of the compound having a phenolic hydroxyl group may be 2000 or less, 94 to 2000, 108 to 2000, or 108 to 1500 in consideration of the balance among solubility in an aqueous alkali solution, photosensitive characteristics, and mechanical characteristics.

The acrylic resin (D) may be, for example, a polymer having a structural unit represented by the following formula (2). In the formula (2), R3 represents a hydrogen atom or a methyl group.

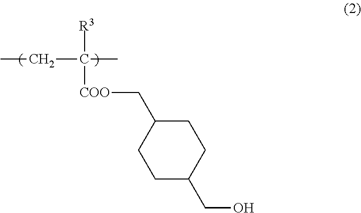

Examples of the monomer giving the structural unit represented by the formula (2) include 1,4-cyclohexanedimethanol mono(meth)acrylate.

After the redistribution layer 3 is formed, as shown in FIG. 2g, the sealing structure 5 is ground to an arbitrary thickness from the surface opposite to the connection surface S. The grinding method may be, for example, mechanical grinding using a grindstone such as a grinder widely applied in a semiconductor manufacture step. Only the sealing layer 1 may be ground or a portion of the chip main body portion 11 may be ground along with the sealing layer 1. The sealing structure 5 may not be ground.

Subsequently, as shown in FIG. 2(h), the solder ball 30 connected to the wiring 31 is provided on the surface opposite to the sealing structure 5 of the redistribution layer 3, and the sealing structure 5 is divided together with the redistribution layer 3 to obtain an individualized the semiconductor device 100. A method of forming the solder ball 30 and a method of dividing the sealing structure 5 and the redistribution layer 3 are not particularly limited. For example, N2 reflow equipment and reagents such as fluxes can be used to form the solder ball 30. For example, a dicer can be used to divide the sealing structure 5 and the redistribution layer 3.

### EXAMPLES

The present invention is not limited to the following examples.

### 1. Temporary Fixing Material

A film temporary fixing material having a thickness of 30 μm, 60 μm, 120 μm, or 150 μm was prepared. The temporary fixing material having a thickness of 30 μm, 60 μm, or 120 μm was a single-layer film, and the temporary fixing material having a thickness of 150 μm was a laminated film including two resin layers.

### 2. Support

A planar support having the thickness and tensile elastic modulus shown in Table 1 was prepared. The Young's modulus shown in Table 1 is a tensile elastic modulus measured in an environment of 23° C.

TABLE 1

| Support | 1 | 2 | 3 | 4 | 5 |
|---|---|---|---|---|---|
| Material | Glass | Copper | SUS | Polyimide | Polyimide |
| Thickness | 1100 | 1000 | 900 | 125 | 250 |
| [μm] | | | | | |
| Young's | 120 | 120 | 200 | 3.3 | 3.3 |
| modulus | | | | | |
| [GPa] | | | | | |

### 3. Molding Test

A temporary fixing material was bonded onto a support having a square main surface of 320 mm×320 mm to prepare a carrier substrate which is a laminate composed of a support and a temporary fixing material layer. Twenty five each of three types of semiconductor chips having a thickness of 150 μm were arranged in each temporary fixing material layer. A sealing layer for sealing a semiconductor chip was formed using a granular or film sealing material. When a granular sealing material was used, a semiconductor chip was arranged in a mold interior of a compression molding apparatus together with a carrier substrate, the sealing material was put in the mold interior, and a sealing layer having a thickness of 200 μm was formed by compression molding. When the sealing material of film was used, the sealing material was laminated on the semiconductor chip side surface of the carrier substrate, and the laminated sealing material was heated to form a sealing layer having a thickness of 200 μm. After the sealing layer was formed, the carrier substrate was peeled from the sealing structure.

After the carrier substrate was peeled off, the step formed by the semiconductor chip and the sealing layer was measured by a contact-type surface profilometer at 20 locations on the connection surface to which the semiconductor chip was exposed.

TABLE 2

| | | Examples | | Comparative Examples | | | | |
|---|---|---|---|---|---|---|---|---|
| | | 1 | 2 | 1 | 2 | 3 | 4 | 5 |
| Support | number | 1 | 1 | 1 | 1 | 1 | 1 | 1 |
| | thickness | 1100 | 1100 | 1100 | 1100 | 1100 | 1100 | 1100 |
| | [μm] | | | | | | | |
| | young's | 120 | 120 | 120 | 120 | 120 | 120 | 120 |
| | modulus | | | | | | | |
| | [GPa] | | | | | | | |
| Temporary | thickness | 30 | 30 | 60 | 60 | 120 | 150 | 150 |
| fixing | [μm] | | | | | | | |
| material | | | | | | | | |
| layer | | | | | | | | |
| Sealing | Sealing | Film | Granules | Film | Granules | Film | Film | Granules |
| layer | material | | | | | | | |
| | Molding | Lam. | Comp. | Lam. | Comp. | Lam. | Lam. | Comp. |
| | method | | | | | | | |

| | | | | | | | |
|---|---|---|---|---|---|---|---|
| Step [μm] | 4.5 | 3.2 | 7.8 | 6.5 | 10.8 | 8.9 | 8.0 |

TABLE 3

| | | Examples | | Comparative Examples | | |
|---|---|---|---|---|---|---|
| | | 1 | 3 | 4 | 6 | 7 |
| Support | number | 1 | 2 | 3 | 4 | 5 |
| | thickness | 1100 | 1000 | 900 | 125 | 250 |
| | [μm] | | | | | |
| | young's | 120 | 120 | 200 | 3.3 | 3.3 |
| | modulus | | | | | |
| | [GPa] | | | | | |
| Temporary | thickness | 30 | 30 | 30 | 30 | 30 |
| fixing | [μm] | | | | | |
| material | | | | | | |
| layer | | | | | | |
| Sealing | Sealing | Film | Film | Film | Film | Film |
| layer | material | | | | | |
| | Molding | Lam. | Lam. | Lam. | Lam. | Lam. |
| | method | | | | | |

| | | | | | |
|---|---|---|---|---|---|
| Step [μm] | 4.5 | 4.9 | 4.4 | 10.2 | 10.8 |

From the results shown in Table 2, it was confirmed that when the thickness of the temporary fixing material layer was reduced, the step tended to be significantly reduced. From the results shown in Table 3, it was confirmed that when the tensile elastic modulus of the support was high, the step tended to be significantly reduced. By selecting the tensile elastic modulus of the support and the thickness of the temporary fixing material layer based on these tendencies, the step formed by the semiconductor chip and the sealing layer can be adjusted to a range of 5.0 μm or less.

### INDUSTRIAL APPLICABILITY

According to the method of the present disclosure, it is possible to reduce a minute step between a semiconductor chip and a sealing layer generated during an assembly process of a fan-out wafer level package regardless of the type of a temporary fixing material layer. As a result, it is possible to manufacture a more highly functional semiconductor device while suppressing the manufacturing cost.

### REFERENCE SIGNS LIST

1: sealing layer, 1A: sealing material, 3: redistribution layer, 5: sealing structure, 10: semiconductor chip, 11: chip main body portion, 12: electrode pad, 31: wiring, 32: insulating layer, 40: carrier substrate, 41: support, 42: temporary fixing material layer, 51, 52: mold, 100: semiconductor device, S: connection surface, G: step.

1. A method of manufacturing a semiconductor device, comprising:
preparing a carrier substrate comprising a support and a temporary fixing material layer provided on the support;
arranging a semiconductor chip comprising a chip main body portion and an electrode pad provided on an outer surface of the chip main body portion on the temporary fixing material layer;
forming a sealing layer sealing the semiconductor chip, thereby forming a sealing structure comprising the semiconductor chip and the sealing layer on the carrier substrate, the sealing structure comprising a connection surface in contact with the temporary fixing material layer, the semiconductor chip being exposed to the connection surface, and a step formed by the semiconductor chip and the sealing layer on the connection surface being 5.0 μm or less;
separating the carrier substrate from the sealing structure; and
providing a redistribution layer comprising multilayer wirings connected to the electrode pad and an insulating layer filling a space between the wirings on the connection surface of the sealing structure.

2. The method according to claim 1, wherein a thickness of the temporary fixing material layer is 50 μm or less.

3. The method according to claim 1, wherein a thickness of the temporary fixing material layer is more than 10 μm and 50 μm or less.

4. The method according to claim 1, wherein a tensile elastic modulus of the support at 23° C. is 100 GPa or more.

5. The method according to claim 1, wherein the support is a glass plate, a metal plate, a silicon wafer, or a ceramic plate.

6. The method according to claim 1, wherein a thickness of the temporary fixing material layer and a tensile elastic modulus of the support at 23° C. are selected in a range such that the step is 5.0 μm or less.

7. The method according to claim 6, wherein a thickness of the temporary fixing material layer is selected in a range of 50 μm or less.

8. The method according to claim 6, wherein a thickness of the temporary fixing material layer is selected in a range of more than 10 μm and 50 μm or less.

9. The method according to claim 6, wherein the tensile elastic modulus of the support at 23° C. is selected in the range of 100 GPa or more.

10. The method according to claim 6, wherein the support is selected from a glass plate, a metal plate, a silicon wafer, and a ceramic plate.

11. The method according to claim 1, wherein the insulating layer comprises an intermediate layer interposed between the wirings and the sealing structure, and a maximum value of a thickness of the intermediate layer is 15 μm or less.

12. The method according to claim 1, wherein the sealing layer is formed by compression molding comprising heating and pressurizing a granular sealing material comprising a curable resin and an inorganic filler in a mold.

13. The method according to claim 1, wherein the sealing layer is formed by a method comprising laminating a film-shaped sealing material comprising a curable resin and an inorganic filler on the carrier substrate.

14.-17. (canceled)
